(19) United States
(12) Patent Application Publication
(10) Pub. No.: US 2009/0267075 A1
(43) Pub. Date: Oct. 29, 2009

(54) OGANIC THIN FILM TRANSISTOR AND PIXEL STRUCTURE AND METHOD FOR MANUFACTURING THE SAME AND DISPLAY PANEL

(75) Inventors: Yi-Kai Wang, Hsinchu City (TW); Tsung-Hsien Lin, Hsinchu City (TW); Jing-Yi Yan, Taoyuan County (TW); Jia-Chong Ho, Hsinchu County (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(73) Assignee: INDUSTRIAL TECHNOLOGY RESEARCH INSTITUTE, Hsinchu (TW)

(21) Appl. No.: 12/371,925

(22) Filed: Feb. 17, 2009

(30) Foreign Application Priority Data
Apr. 23, 2008 (TW) 97114886

(51) Int. Cl. H01L 51/52; H01L 21/336

(52) U.S. Cl. 257/72; 438/158; 438/29; 257/40; 313/504; 257/E51.018; 257/E21.414

(57) ABSTRACT

A method of manufacturing an organic thin film transistor is described. A patterned insulating layer having an opening therein is formed on a substrate. A gate is formed in the opening of the insulating layer, and a gate insulating layer is formed on the gate. A conductive material layer is formed on the gate insulating layer by a printing process. One of the gate insulating layer and the conductive material layer is hydrophobic or hydrophilic and the other is hydrophilic or hydrophobic, such that the conductive material layer is naturally separated to two sides of the gate insulating layer to form a source and a drain. An active layer is formed on the gate insulating layer between the source and the drain.

### CROSS-REFERENCE TO RELATED APPLICATION

This application claims the priority benefit of Taiwan application serial no. 97114886, filed on Apr. 23, 2008. The entirety of the above-mentioned patent application is hereby incorporated by reference herein and made a part of specification.

### BACKGROUND OF THE INVENTION

1. Field of the Invention

The present invention relates to a method for manufacturing a thin film transistor and a pixel structure, in particularly, to a method for manufacturing an organic thin film transistor and a pixel structure, a method for manufacturing the same, and a display panel having the pixel structure.

2. Description of Related Art

Among various flat-panel displays, organic light-emitting displays (OLED) will most probably challenge the liquid crystal display (LCD) apparatuses in the future. The OLED is substantially made a material of organic compounds, and has many advantages such as high contrast, high brightness, wide viewing angle, quick speed, less power consumption, “light, thin, short, and small,” and flexibility that LCD apparatuses lacks. However, the OLED still has some disadvantages to be overcome. For example, the service life of the OLED needs to be extended, the fabrication technique of the devices is not as mature as that of the LCD apparatuses, and the fabrication yield is relatively low.

In a common AM-OLED structure, a passivation layer is fabricated by a high-temperature process, and conductive vias are formed therein to achieve the current transmission. Or, a passivation layer is patterned to expose the pixel electrode, so as to achieve the current transmission. Although it is not difficult to fabricate the passivation layer of the conventional inorganic thin film transistor, regarding an organic thin film transistor containing an organic material, the high-temperature fabrication process of the passivation layer or the process for forming the conductive vias is liable to deteriorate the characteristics of the devices of the organic thin film transistor. When fabricating the passivation layer by a photolithography process, the characteristics of the devices may also be affected by the material residues of the passivation layer, which results in the drift of the characteristics of the devices after the subsequent processes.

### SUMMARY OF THE INVENTION

Accordingly, the present invention is related to provide a method for manufacturing an organic thin film transistor, which includes the following steps. A patterned insulating layer having an opening therein is formed on a substrate. A gate is formed in the opening of the insulating layer. A gate insulating layer is formed on the gate. A conductive material layer is formed on the gate insulating layer by a printing process. One of the gate insulating layer and the conductive material layer is hydrophobic or hydrophilic and the other is hydrophilic or hydrophobic, such that the conductive material layer is naturally separated to two sides of the gate insulating layer to form a source and a drain. An active layer is formed on the gate insulating layer between the source and the drain.

The present invention further provides a method for manufacturing a pixel structure, which includes the following steps. At least one organic thin film transistor and an anode layer electrically connected to the organic thin film transistor are formed on the substrate. The organic thin film transistor includes a gate, a gate insulating layer, a source, a drain, and an active layer. A patterned insulating layer is formed above the substrate by a printing process. The patterned insulating layer exposes the anode layer. An organic light-emitting layer is formed on an exposed surface of the anode layer. Then, a cathode layer is formed on the organic light-emitting layer.

The present invention further provides a pixel structure, which includes at least one organic thin film transistor, an anode layer, a patterned insulating layer, an organic light-emitting layer, and a cathode layer. The organic thin film transistor is disposed on the substrate and includes a gate, a gate insulating layer, a source, a drain, and an active layer. The anode layer is disposed on the substrate and is electrically connected to the organic thin film transistor. The patterned insulating layer is disposed on the substrate and exposes the anode layer. The organic light-emitting layer is disposed on an exposed surface of the anode layer. The cathode layer covers the organic light-emitting layer. The cathode layer does not extend to above the active layer of the organic thin film transistor.

The present invention further provides an organic light-emitting display panel, which includes a substrate, data lines, scan lines, power supply lines, a pixel array, and a protection structure. The data lines, the scan lines, and the power supply lines are disposed on the substrate. The pixel array is disposed on the substrate, and pixels are electrically connected to one of the data lines, one of the scan lines, and one of the power supply lines. Each of the pixels includes at least one organic thin film transistor, and the organic thin film transistor includes a gate, a gate insulating layer, a source, a drain, and an active layer. The anode layer is disposed on the substrate and is electrically connected to the organic thin film transistor. The patterned insulating layer is disposed on the substrate and exposes the anode layer. The organic light-emitting layer is disposed on an exposed surface of the anode layer. The cathode layer covers the organic light-emitting layer. The cathode layer does not extend to above the active layer of the organic thin film transistor. Furthermore, the protection structure is disposed above the substrate and isolates the pixel array from outside.

In order to the make the present invention comprehensible, embodiments accompanied with figures are described in detail below.

### BRIEF DESCRIPTION OF THE DRAWINGS

The accompanying drawings are included to provide a further understanding of the invention, and are incorporated in and constitute a part of this specification. The drawings illustrate embodiments of the invention and, together with the description, serve to explain the principles of the invention.

FIG. 1 is an equivalent circuit diagram of a pixel array according to an embodiment of the present invention.

FIGS. 2A and 2B are schematic cross-sectional views of pixel structures according to different embodiments of present invention.

FIGS. 3 and 4 are schematic cross-sectional views of organic light-emitting display panels according to different embodiments of present invention.

FIGS. 5A-10A and FIGS. 5B-10B are schematic views of processes for manufacturing an organic thin film transistor according to an embodiment of the present invention, in which FIGS. 5A-10A are cross-sectional views illustrating different steps, and FIGS. 5B-10B are top views.

FIGS. 11A-11F are top views of schematic vies of processes for manufacturing an organic thin film transistor according to another embodiment of the present invention.

### DESCRIPTION OF THE EMBODIMENTS

Reference will now be made in detail to the present embodiments of the invention, examples of which are illustrated in the accompanying drawings. Wherever possible, the same reference numbers are used in the drawings and the description to refer to the same or like parts.

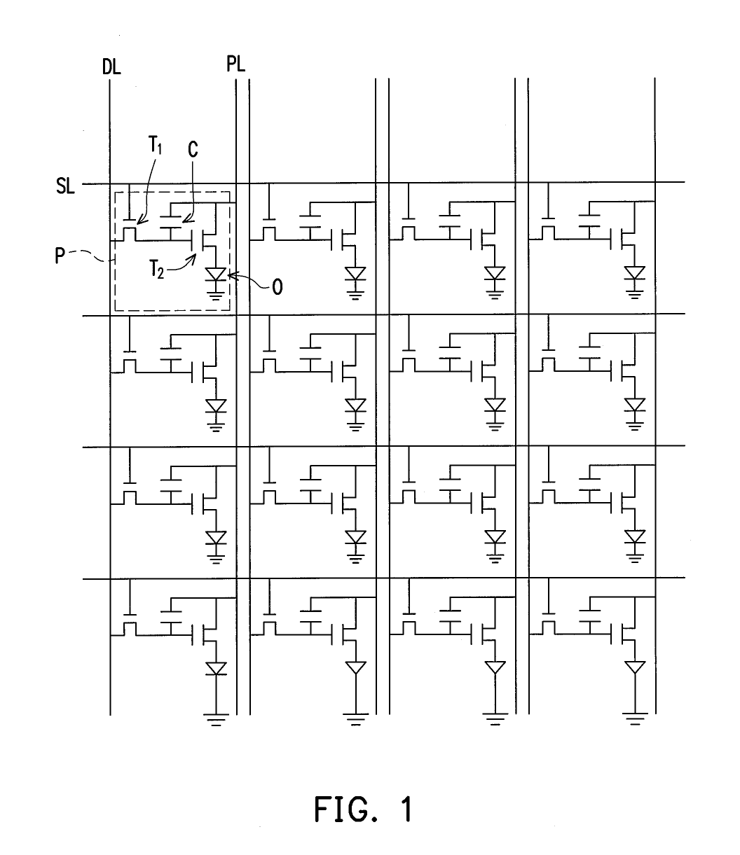

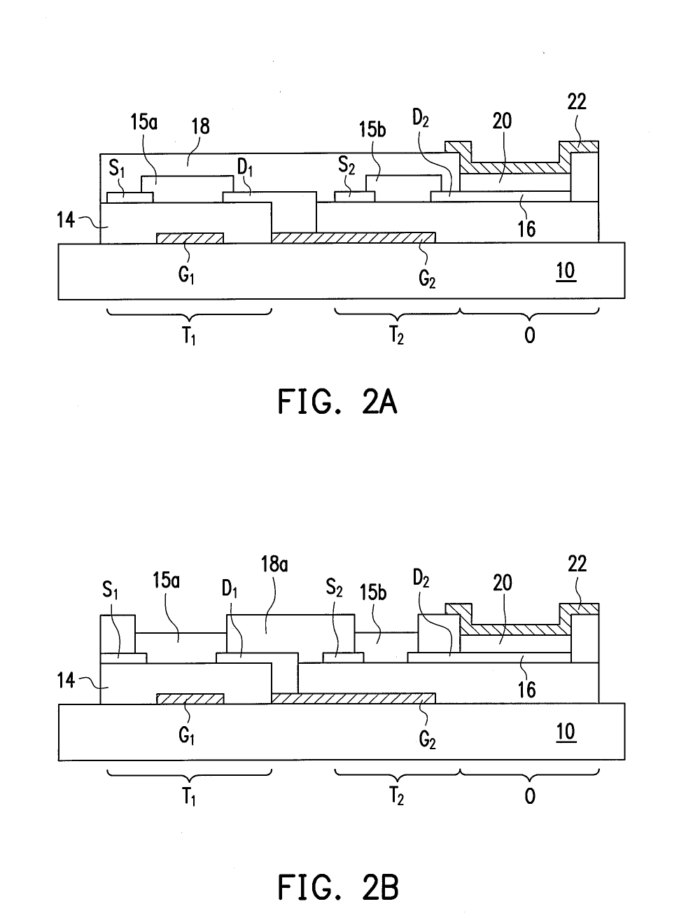

FIG. 1 is an equivalent circuit diagram of a pixel array according to an embodiment of the present invention, and FIG. 2A is a schematic cross-sectional view of a pixel structure in a pixel array. Referring to FIGS. 1 and 2A, the pixel array is disposed on the substrate and includes a plurality of data lines DL, a plurality of scan lines SL, a plurality of power supply lines PL, and a plurality of pixel structures P. Each of the pixel structures P is electrically connected to one of the data lines DL, one of the scan lines SL, and one of the power supply lines PL. Each of the pixel structures P includes at least one organic thin film transistor T1, T2, a capacitor C, and an organic light-emitting diode (OLED) O. In this embodiment, the devices of the pixel structure P are illustrated by, but not limited to, 2T1C. In the present invention, the number of the organic thin film transistor and the capacitor in each pixel structure P is not limited. In the pixel structure P in the form of 2T1C, the source of the organic thin film transistor T1 is connected to the data lines DL, the gate is electrically connected to the scan lines SL, and the drain is connected to the gate of the organic thin film transistor T2. The gate of the organic thin film transistor T2 is electrically connected to the drain of the organic thin film transistor T1, the source is electrically connected to the power supply lines PL, and the drain is electrically connected to the OLED O. One end of the capacitor C is electrically connected to the drain of the organic thin film transistor T1 and the gate of the organic thin film transistor T2. The other end of the capacitor C is electrically connected to the source of the organic thin film transistor T2 and the power supply lines PL.

Hereinafter, the films that compose each pixel structure P are illustrated with reference to FIG. 2A together with FIG. 1. Referring to FIGS. 1 and 2A, the pixel structure includes an organic thin film transistor T1, an organic thin film transistor T2, a capacitor C (as shown in FIG. 1), and an OLED O disposed on a substrate 10. The organic thin film transistor T1 includes a gate G1, a source S1, a drain D1, and an active layer 15a, and the gate G1 and the source S1/drain D1 are isolated by a gate insulating layer 14. The organic thin film transistor T2 includes a gate G2, a source S2, a drain D2, an active layer 15b, and the gate G2 and the source S2/drain D2 are isolated by the gate insulating layer 14. One end of the capacitor C is electrically connected to the drain of the organic thin film transistor T1, and the other end of the capacitor C is electrically connected to the source of the organic thin film transistor T2 (as shown in FIG. 1). A material of the active layers 15a, 15b is an organic semiconductor material.

Further, the OLED O includes an anode layer 16, an organic light-emitting layer 20, and a cathode layer 22. The OLED O and the transistors T1, T2 are isolated by a patterned insulating layer 18. The anode layer 16 is connected to the drain D2 of the organic thin film transistor T2. In an embodiment, the materials of the anode layer 16 and the source/drain S2/D2, S1/D1 are the same, for example, transparent metal oxide, such as indium-tin oxide (ITO) or indium-zinc oxide (IZO). The patterned insulating layer 18 covers the organic thin film transistors T1, T2 and exposes the anode layer 16. The organic light-emitting layer 20 is disposed on a surface of the anode layer 16. The cathode layer covers the organic light-emitting layer 20, but does not extend to above the organic thin film transistors T1, T2.

The method for manufacturing the pixel structure includes the following steps. First, an organic thin film transistor and a capacitor are formed by a conventional method. That is, a gate, a gate insulating layer, a source/drain, and an active layer of the organic thin film transistor T1, T2 and an electrode end, a capacitor dielectric layer, another electrode end of the capacitor C, and an anode layer of the OLED O are formed in sequence by deposition processes and photolithography and etching processes. In an embodiment, the anode layer of the OLED O and the source and the drain of the organic thin film transistor are defined at the same time, that is, through the same one process.

After the fabrication of the above devices is completed, a patterned insulating layer 18 is formed by a printing process. The printing process may be an ink-jet printing, a screen printing, an imprinting, or a contact printing process. Since the printing process for forming the patterned insulating layer 18 is a method capable of directly forming a patterned film, the formed patterned film 18 already has a specific pattern without going through a deposition and etching process. Therefore, after the printing process is completed, the formed patterned insulating layer 18 exposes the anode layer 16.

Thereafter, an organic light-emitting layer 20 is formed on the anode layer 16, and a cathode layer 22 is formed on the organic light-emitting layer 20.

FIG. 2A shows an embodiment of the patterned insulating layer 18 exposing the anode layer 16. In another embodiment of the present invention, in addition to the anode layer 16, the patterned insulating layer further exposes a predetermined position for forming the active layer. Referring to FIG. 2B, in the pixel structure as shown in FIG. 2B, after the fabrication of the source/drain of the organic thin film transistor is completed, a patterned insulating layer 18a is formed by the printing process, so as to expose the anode layer 16 and the gate insulating layer 14 right above the gates G1, G2. After that, an organic light-emitting layer 20 is directly formed on the anode layer 16, and active layers 15a, 15b are formed on the gate insulating layer 14 right above the gates G1, G2. Thereafter, a cathode layer 22 is formed and does not extend to above the organic thin film transistors T1, T2.

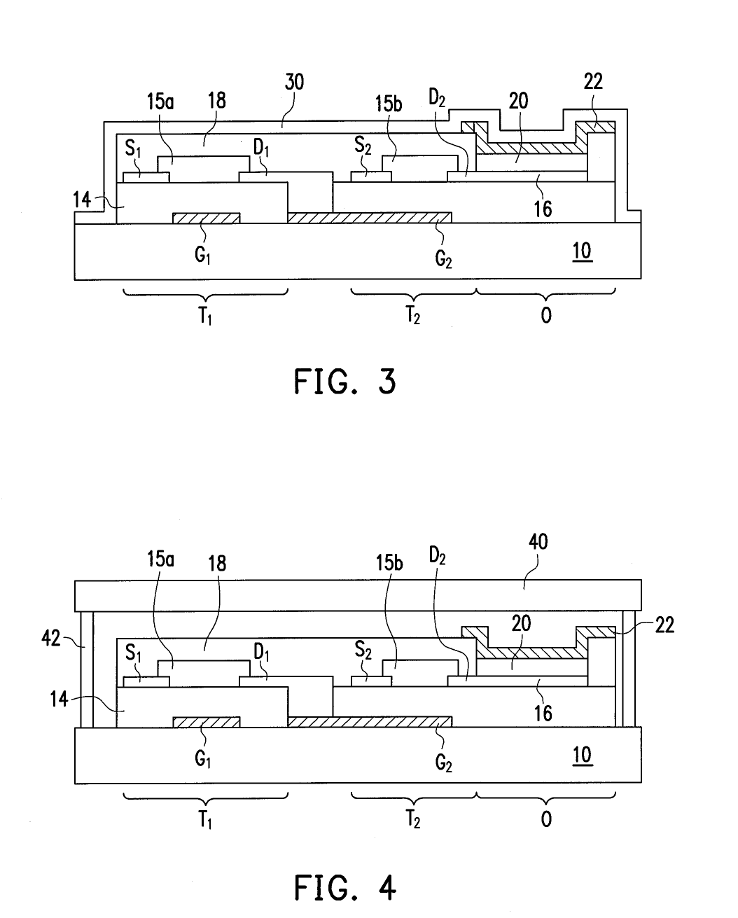

Usually, after the pixel array is fabricated, a protection structure may be formed on the pixel array to form an organic light-emitting display panel. Referring to FIG. 3, a protective film 30 is formed on the pixel array to isolate the pixel array from the outside. In another embodiment, referring to FIG. 4, the protection structure formed on the pixel array includes a cover 40 and a sealant 42. That is, the sealant 42 assembles the substrate 10 and the cover 40 together, so as to seal the pixel array between the substrate 10 and the cover 40. The two protection structures have been disclosed in the prior arts and will not be illustrated in detail herein.

In the above embodiments, the organic thin film transistor is formed by conventional processes, and then the patterned insulating layer is formed by the printing process, so as to avoid the deterioration of the characteristics of the devices caused by the high-temperature deposition process and the etching process in the conventional deposition and etching method for forming the passivation insulating layer. The present invention further provides a special method for forming the organic thin film transistor, which will be described as follows.

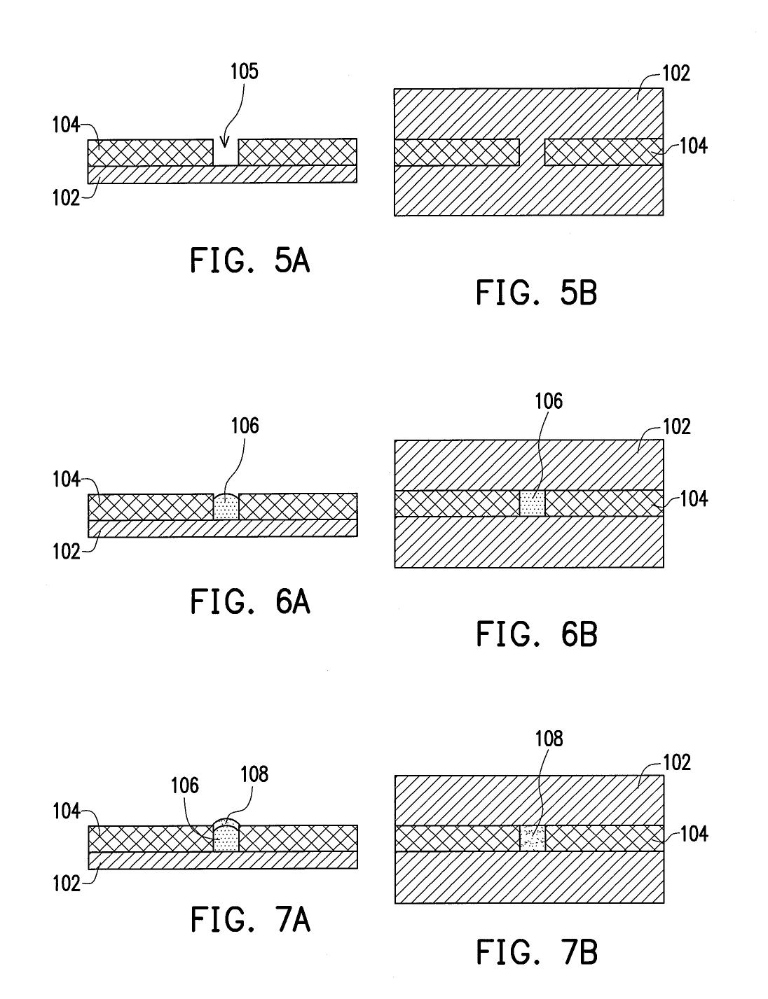

FIGS. 5A-10A and FIGS. 5B-10B are schematic views of processes for manufacturing an organic thin film transistor according to an embodiment of the present invention, in which FIGS. 5A-10A are cross-sectional views illustrating different steps, and FIGS. 5B-10B are top views. Referring to FIGS. 5A and 5B, a patterned insulating layer 104 having an opening 105 is formed on a substrate 102. The substrate 102 may be a rigid substrate, such as glass, quartz, or silicon wafer, and may also be a flexible substrate, such as plastic or metal sheet.

A material of the insulating layer 104 may be a non-conductive material, such as an organic material, an inorganic material, an organic-inorganic mixed material, or a composite material. The insulating layer 104 may be fabricated by a printing process or a laser patterning technique. The printing process includes, for example, an ink-jet printing, a screen printing, an imprinting, or a contact printing process. The laser patterning technique includes laser transfer and laser etching.

Then, as shown in FIGS. 6A and 6B, a gate 106 is formed in the opening 105 of the patterned insulating layer 104. A method for forming the gate 106 includes spin casting, printing, or deposition. Since the pre-formed patterned insulating layer 104 has defined the position of the gate 106 (i.e., the position of the opening 105), the step for forming the gate 106 may be performed in the absence of a mask.

Thereafter, as shown in FIGS. 7A and 7B, a gate insulating layer 108 is formed on the gate 106 by performing, for example, a printing process or any other processes. In this step, the gate insulating layer 108 may be defined by the position of the opening 105 of the insulating layer 104, and thus the mask for patterning is omitted. The gate insulating layer 108 may be made of an inorganic material, such as silicon oxide or silicon nitride, or an organic material, such as fluorine-based polymer, polyimide (PI), polymethyl methacrylate (PMMA), polyvinyl alcohol (PVA), polyvinyl phenol (PVP), or a mixture thereof, and may also be made of an organic-inorganic mixed material or a composite material.

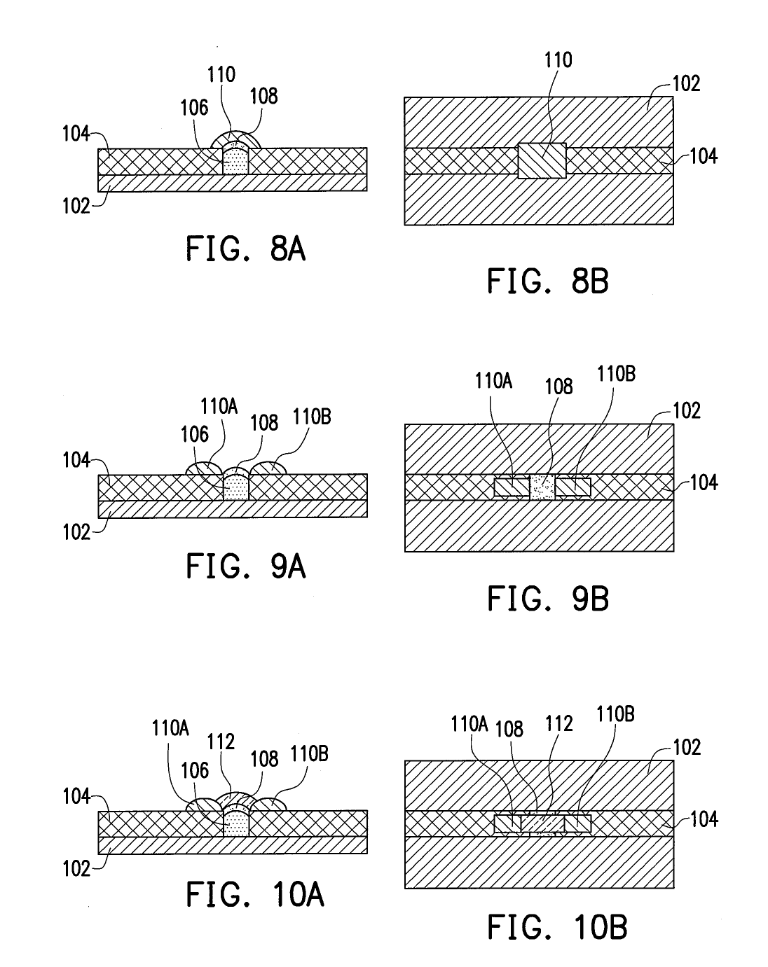

Then, as shown in FIGS. 8A and 8B, a conductive material layer 110 is formed above the gate insulating layer 108 by the printing process. One of the gate insulating layer 108 and the conductive material layer 110 is hydrophobic or hydrophilic and the other is hydrophilic or hydrophobic, such that conductive material layer 110 is naturally separated to two sides of the gate insulating layer 108 to form a source 110A and a drain 110B (as shown in FIGS. 9A and 9B). In other words, if the gate insulating layer 108 is hydrophobic, the conductive material layer 110 is hydrophilic. On the contrary, if gate insulating layer 108 is hydrophilic, the conductive material layer 110 is hydrophobic. A material of the conductive material layer 110 includes nano-gold, nano-silver, silver paste, poly(3,4-ethylene dioxy-thiophene) (PEDOT) or a transparent conductive material. For example, if the fluorine-based polymer is used to fabricate the gate insulating layer 108, the silver paste may be used to fabricate the conductive material layer 110. In another example, if the polyvinyl alcohol is used to fabricate the gate insulating layer 108, the PEDOT may be used to fabricate the conductive material layer 110.

Thereafter, as shown in FIGS. 10A and 10B, an active layer 112 is formed on the gate insulating layer 108 between the source 110A and the drain 110B by, for example, the printing process. A material of the active layer 112 is, for example, an organic semiconductor material.

The present invention provides a method for manufacturing an organic thin film transistor, such as a printing process. The films of the organic thin film transistor may be fabricated by the printing, so as to reduce the use of the mask and vacuum process and equipment, thus simplifying the process. Further, since the source and the drain are fabricated based on the hydrophobic or hydrophilic property of the liquid drops, the formed source/drain and gate will not be overlapped, thus reducing the parasitic-capacitance in the transistor device.

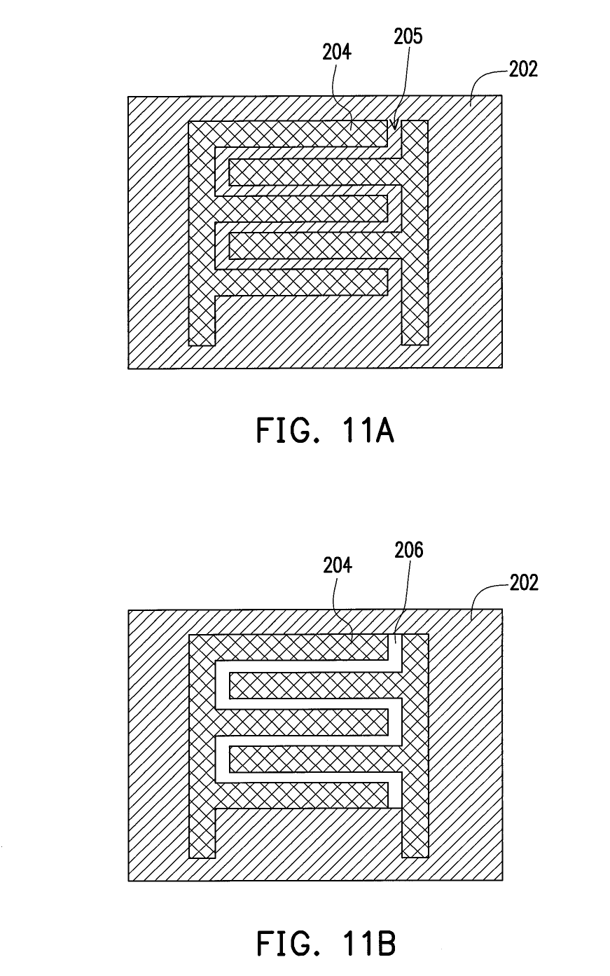

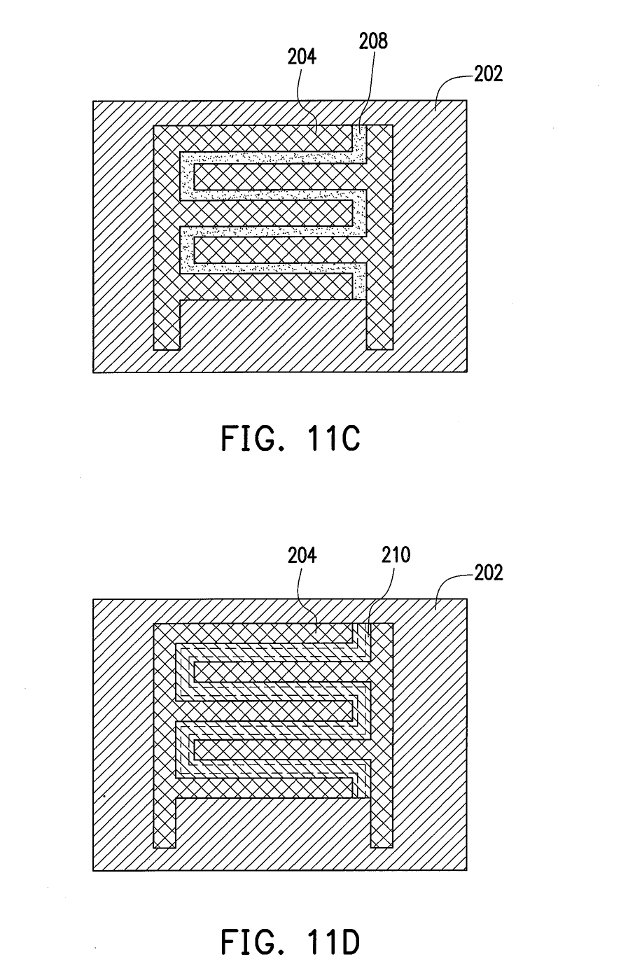

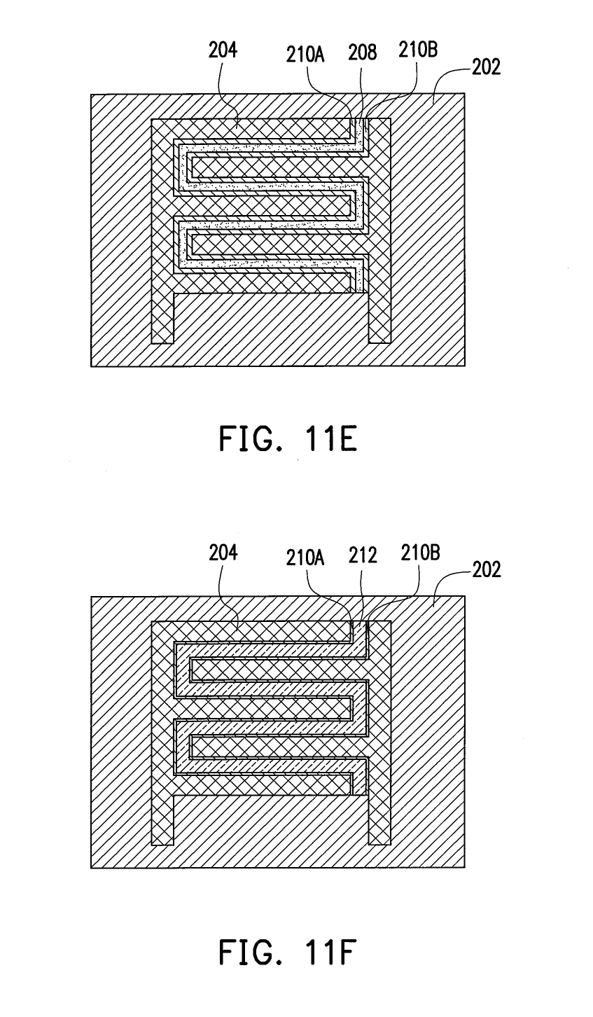

The organic thin film transistor of the embodiments may also be formed to have a comb pattern structure described in the above embodiments. FIGS. 11A-11F are top views of an organic thin film transistor having a comb pattern structure fabricated according to another embodiment of the present invention.

First, referring to FIG. 11A, an insulating layer 204 having an opening 205 therein is formed on a substrate 202, and thus an insulating layer 204 with a comb pattern is formed. Next, as shown in FIG. 11B, a gate 206 is formed in the opening 205 by, for example, a spin casting, a printing, or a deposition process.

Then, as shown in FIG. 11C, a gate insulating layer 208 is formed on the gate 206 by, for example, a printing process or any other processes. The gate insulating layer 208 may be made of an inorganic material, such as silicon oxide or silicon nitride, or an organic material, such as PI, PMMA, PVA, PVP, or a mixture thereof, and may also be an organic-inorganic mixed material or a composite material.

Thereafter, as shown in FIG. 11D, a conductive material layer 210 is formed on the gate insulating layer 208 by the printing process. One of the gate insulating layer 208 and the conductive material layer 210 is hydrophobic or hydrophilic and the other is hydrophilic or hydrophobic, such that the conductive material layer 210 is naturally separated to two sides of the gate insulating layer 208 to form a source 210A and a drain 210B (as shown in FIG. 11E). In other words, if the gate insulating layer 208 is hydrophobic, the conductive material layer 210 is hydrophilic. On the contrary, if the gate insulating layer 208 is hydrophilic, the conductive material layer 210 is hydrophobic.

Next, as shown in FIG. 11F, an active layer 212 is formed on the gate insulating layer 208 between the source 210A and the drain 210B by, for example, the printing process. A material of the active layer 212 is, for example, an organic semiconductor material.

After the fabrication of the organic thin film transistor as shown in FIGS. 5A to 10A and FIGS. 5B to 10B or the thin film transistor as shown in FIGS. 11A to 11F is completed, a step of fabricating the OLED may be performed, i.e., the step as shown in FIG. 2A or 2B is used in combination so as to complete the fabrication of the pixel structure. That is to say, after the fabrication of the organic thin film transistor is completed, the patterned insulating layer is first formed by the printing process, and then the organic light-emitting layer and the cathode layer are formed. The fabrication of the protection structure may be performed (as shown in FIG. 3 or 4) on the pixel structure formed by the pixel array obtained in the above manner, so as to form the organic light-emitting display panel.

In view of the above, the insulating layer in the pixel structure of the present invention is a specific pattern structure directly formed by the printing process, thus avoiding the deterioration of the characteristics of the devices caused by the conventional high-temperature processes for fabricating the insulating layer and the impacts of the residues of the insulating layer on the characteristics of the devices and the light transmittance. Since the patterning process such as etching is not required additionally, the deterioration of the characteristics of the devices of the organic thin film transistor caused by the patterning process can be avoided.

Furthermore, in the organic thin film transistor, the source and the drain are formed on the gate insulating layer based on the hydrophilic and hydrophobic properties of the materials, so the source/drain and the gate are not overlapped, thus reducing the parasitic-capacitance between the source/drain and the gate in the transistor device.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A method for manufacturing an organic thin film transistor, comprising:
forming a patterned insulating layer having an opening therein on a substrate;
forming a gate in the opening of the insulating layer;
forming a gate insulating layer on the gate;
forming a conductive material layer on the gate insulating layer by a printing process, wherein one of the gate insulating layer and the conductive material layer is hydrophobic or hydrophilic and the other is hydrophilic or hydrophobic, such that the conductive material layer is naturally separated to two sides of the gate insulating layer to form a source and a drain; and
forming an active layer on the gate insulating layer between the source and the drain.

2. The method for manufacturing an organic thin film transistor according to claim 1, wherein the printing process comprises an ink-jet printing, a screen printing, an imprinting, or a contact printing process.

3. The method for manufacturing an organic thin film transistor according to claim 1, wherein a process for forming the patterned insulating layer comprises printing or laser patterning.

4. The method for manufacturing an organic thin film transistor according to claim 1, wherein a process for forming the active layer on the gate insulating layer between the source and the drain comprises printing.

5. The method for manufacturing an organic thin film transistor according to claim 1, wherein a process for forming the gate insulating layer on the gate comprises printing.

6. The method for manufacturing an organic thin film transistor according to claim 1, wherein a process for forming the gate in the opening of the insulating layer comprises spin casting, printing, or deposition.

7. The method for manufacturing an organic thin film transistor according to claim 1, wherein a material of the gate insulating layer comprises an inorganic material selected from among silicon oxide or silicon nitride.

8. The method for manufacturing an organic thin film transistor according to claim 1, wherein a material of the gate insulating layer comprises an organic material selected from among fluorine-based polymer, polyimide (PI), polymethyl methacrylate (PMMA), polyvinyl alcohol (PVA), polyvinyl phenol (PVP), or a mixture thereof.

9. The method for manufacturing an organic thin film transistor according to claim 1, wherein a material of the conductive material layer comprises nano-gold, nano-silver, silver paste, poly(3,4-ethylene dioxy-thiophene) (PEDOT) or a transparent conductive material.

10. The method for manufacturing an organic thin film transistor according to claim 1, wherein the patterned insulating layer is of a comb pattern structure.

11. A method for manufacturing a pixel structure, comprising:
forming at least one organic thin film transistor and an anode layer electrically connected to the organic thin film transistor on a substrate, wherein the organic thin film transistor comprises a gate, a gate insulating layer, a source, a drain, and an active layer;
forming a patterned insulating layer above the substrate by a printing process, wherein the patterned insulating layer exposes the anode layer;
forming an organic light-emitting layer on an exposed surface of the anode layer; and
forming a cathode layer on the organic light-emitting layer.

12. The method for manufacturing a pixel structure according to claim 11, wherein the printing process comprises an ink-jet printing, a screen printing, or a contact printing process.

13. The method for manufacturing a pixel structure according to claim 11, wherein a process for forming the organic thin film transistor on the substrate comprises:
forming a patterned insulating layer having an opening therein on the substrate;
forming a gate in the opening of the insulating layer;
forming a gate insulating layer on the gate;
forming a conductive material layer on the gate insulating layer by a printing process, wherein one of the gate insulating layer and the conductive material layer is hydrophobic or hydrophilic and the other is hydrophilic or hydrophobic, such that the conductive material layer is naturally separated to two sides of the gate insulating layer to form a source and a drain; and
forming an active layer on the gate insulating layer between the source and the drain.

14. The method for manufacturing a pixel structure according to claim 11, wherein a process for forming the organic thin film transistor on the substrate comprises:
forming the gate on the substrate;
forming the gate insulating layer on the gate;
forming the source and the drain on the gate insulating layer; and
forming the active layer on the gate insulating layer between the source and the drain.

15. The method for manufacturing a pixel structure according to claim 11, wherein the patterned insulating layer further exposes the active layer of the organic thin film transistor, and the cathode layer does not extend to above the active layer of the organic thin film transistor.

16. The method for manufacturing a pixel structure according to claim 11, wherein the anode layer and the source and the drain of the organic thin film transistor are defined at the same time.

17. A pixel structure, comprising:
at least one organic thin film transistor, disposed on a substrate and comprising a gate, a gate insulating layer, a source, a drain, and an active layer;
an anode layer, disposed on the substrate and electrically connected to the organic thin film transistor;
a patterned insulating layer, disposed on the substrate and exposing the anode layer;
an organic light-emitting layer, disposed on an exposed surface of the anode layer; and
a cathode layer, covering the organic light-emitting layer, wherein the cathode layer does not extend to above the active layer of the organic thin film transistor.

18. The pixel structure according to claim 17, wherein the patterned insulating layer further exposes the active layer of the organic thin film transistor.

19. The pixel structure according to claim 17, wherein a material of the anode layer is as the same as that of the source and the drain of the organic thin film transistor.

20. An organic light-emitting display panel, comprising:
a substrate;
a plurality of data lines, a plurality of scan lines, and a plurality of power supply lines, disposed on the substrate;
a pixel array, disposed on the substrate, and comprising pixels electrically connected to one of the data lines, one of the scan lines, and one of the power supply lines, wherein each pixel comprises:
at least one organic thin film transistor, disposed on a substrate and comprising a gate, a gate insulating layer, a source, a drain, and an active layer;
an anode layer, disposed on the substrate and electrically connected to the organic thin film transistor;
a patterned insulating layer, disposed on the substrate and exposing the anode layer;
an organic light-emitting layer, disposed on an exposed surface of the anode layer; and
a cathode layer, covering the organic light-emitting layer, wherein the cathode layer does not extend to above the active layer of the organic thin film transistor; and
a protection structure, disposed above the substrate, for isolating the pixel array from outside.

21. The organic light-emitting display panel according to claim 20, wherein the patterned insulating layer further exposes the active layer of the organic thin film transistor.

22. The organic light-emitting display panel according to claim 20, wherein a material of the anode layer is the same as that of the source and the drain of the organic thin film transistor.

23. The organic light-emitting display panel according to claim 20, wherein the protection structure comprises a protective film covering the pixel array.

24. The organic light-emitting display panel according to claim 20, wherein the protection structure comprises:
a cover, disposed opposite to the substrate; and
a sealant, disposed on the periphery of the substrate and the cover, for sealing the pixel array between the substrate and the cover.
